(19) United States
(12) Patent Application Publication
(10) Pub. No.: US 2024/0421557 A1
(43) Pub. Date: Dec. 19, 2024

(54) PHOTONIC DEVICE PROVIDED WITH A LASER SOURCE AND MEANS FOR MANAGING DISSIPATION OF HEAT

(71) Applicant: Scintil Photonics, Grenoble Cedex 9 (FR)

(72) Inventors: Sylvie Menezo, Grenoble Cedex 9 (FR); Frédéric Mazur, Grenoble Cedex 9 (FR)

(21) Appl. No.: 18/703,930

(22) PCT Filed: Oct. 13, 2022
(86) PCT No.: PCT/EP2022/078525

§ 371 Date: Apr. 23, 2024

(30) Foreign Application Priority Data
Oct. 29, 2021 (FR) FR2111534
Dec. 7, 2021 (FR) FR2113081

(51) Int. Cl. H01S 5/024; H01S 5/0239; H01S 5/026; H01S 5/042

(52) U.S. Cl. CPC H01S 5/02476; H01S 5/0239; H01S 5/02407; H01S 5/026; H01S 5/0424; H01S 5/04254

(57) ABSTRACT

A photonic device comprises a heterogenous laser source and heat-dissipating means that are configured to dissipate the heat liable to be emitted by the laser source. The heat-dissipating means implements a heat-transferring layer and a heat-transferring element that are arranged to interact with contact pads accessible on the front side of the photonic device and, the heat-transferring layer is made of an electrically insulating material and makes contact with either or both of the contact pads. The heat-transferring element is located exclusively in contact with the heat-transferring layer.

### CROSS-REFERENCE TO RELATED APPLICATIONS

This application is a national phase entry under 35 U.S.C. § 371 of International Patent Application PCT/EP2022/078525, filed Oct. 13, 2022, designating the United States of America and published as International Patent Publication WO 2023/072610 A1 on May 4, 2023, which claims the benefit under Article 8 of the Patent Cooperation Treaty of French Patent Application Serial No. FR2111534, filed Oct. 29, 2021 and French Patent Application Serial No. FR2113081, filed Dec. 7, 2021.

### TECHNICAL FIELD

The present disclosure relates to the fields of microelectronics, optics, electro-optics and photonics. The present disclosure relates, in particular, to a photonic device provided with at least one III-V semiconductor laser source integrated into a silicon substrate and provided with heat-dissipating means, the arrangement of which allows more efficient heat dissipation than the previously known arrangements.

The present disclosure proposes a device for supplying electrical power to one or more lasers integrated on a support, for example, made of silicon, while improving the heat dissipation of the lasers toward a heat dissipation plate.

### BACKGROUND

The document [1] cited at the end of the description discloses a heterogeneous laser device 1. This device 1, as shown in [FIG. 1], comprises, from a rear face 1B to a front face 1A, a support substrate 2, in particular, made of silicon, on a main face 3 of which a photonic layer 4 rests.

In particular, the photonic layer 4 comprises at least one layer of dielectric material and wherein a waveguide 5 and a photonic stack 6 formed from a plurality of layers of III-V semiconductor materials structured in a second waveguide are encapsulated. More particularly, the photonic stack 6 and the waveguide 5 are optically coupled so as to form a heterogeneous laser source.

More particularly, the photonic layer 4, as shown in [FIG. 1], comprises, from the main face 3, a stack of three layers, called, respectively, the first layer 7, second layer 8 and third layer 9. In this respect, the waveguide 5 can be arranged in the first layer 7, flush with the interface formed between the first layer 7 and the second layer 8, while the photonic stack 6, in line with the waveguide 5, can be arranged in the third layer 9, flush with the interface formed between the second layer 8 and the third layer 9.

Furthermore, the device 1 shown in [FIG. 1] also comprises interconnection means provided with contact pads 10A and 10B accessible from the front face 1A and electrically connected to the photonic stack 6 by means of connection vias 11A and 11B, which extend in the photonic layer 4 and more particularly in the third layer 9.

Thus, as soon as a voltage is imposed on each of the contact pads, the photonic stack is capable of emitting laser radiation. This laser radiation is guided in the waveguide 5 and the photonic stack 6, and can, depending on the configuration of the device 1, be injected into an optical fiber or another photonic device via coupling means formed in the device 1.

Also, in order to ensure optimal confinement of the laser radiation in the waveguide, and consequently to limit optical losses, the photonic layer is generally formed of dielectric layers 7, 9 of relatively large thicknesses, for example, on the order of 800 nm, or even greater.

However, in operation, the photonic stack 6 undergoes heating, which, if not controlled, may affect the performance of the device 1 and more particularly of the laser source. In this respect, the dielectric layers forming the photonic layer constitute an obstacle to heat dissipation and consequently increase this heating.

Document [2] cited at the end of the description also proposes a heterogeneous laser device. In particular, this laser device comprises (in accordance with [FIG. 9] of document [2]) a silicon substrate on one face of which sit, in order, a layer of silicon dioxide, a layer of silicon, and a photonic stack. The photonic stack, like that proposed in the document [1], is formed of a plurality of layers of III-V semiconductor materials structured in a waveguide, called a laser guide. In this respect, the laser guide is coupled with a waveguide formed in the silicon layer. This device also comprises heat-dissipating means configured to dissipate the heat that can be produced by the photonic stack. More particularly, the means comprise bridges of poly-crystalline silicon formed in line with the photonic stack and configured to dissipate the heat produced by the photonic stack toward the silicon substrate.

The document [3] cited at the end of the description proposes another architecture in order to control the heat dissipation. More particularly, and as shown in [FIG. 4] (j) of the document [3], the heterogeneous laser device comprises thermal bridges made of metal, and thermally connecting the silicon substrate with the contact pads of the photonic stack.

Finally, the document [4] cited at the end of the description also discloses a photonic device provided with heat-dissipating means configured to dissipate the heat produced by a photonic stack. In particular, the photonic stack is formed of a plurality of layers of III-V semiconductor materials structured in a waveguide, called a laser guide. In this respect, the laser guide is coupled with a waveguide formed in line with the laser guide. In the proposed architecture, the heat-dissipating means comprise metal levels encapsulated in a dielectric layer resting on one face of a support substrate and make it possible to dissipate the heat produced by the photonic stack toward a support substrate.

Nevertheless, the efficiency of the solutions proposed in these documents remains limited.

Therefore, one aim of the present disclosure is to propose a heterogeneous laser device provided with heat-dissipating means, the efficiency of which is improved relative to the solutions known from the prior art.

### BRIEF SUMMARY

The present disclosure relates to a photonic device comprising a photonic chip and a support substrate, the photonic chip comprising a support layer and a photonic layer resting by its face, called the lower face, on a main face of the support layer. The photonic layer, which comprises at least one dielectric material, encapsulates at least one laser source formed by a waveguide and a photonic stack optically coupled to one another, the photonic stack consisting of III-V semi-conductor materials. The photonic chip also comprises a first and a second metal pad having, respectively, a first and a second surface, accessible by an upper face of the photonic layer opposite the lower face, and electrically connected to the photonic stack by way of connection vias, which extend in the photonic layer. The first pad and the second pad are configured to allow the circulation of an electric current in the photonic stack to control the emission of a laser radiation by the laser source. The photonic device further comprises:
first heat-dissipating means configured to dissipate heat capable of being emitted by the laser source, the first means comprising a heat-transferring layer and a heat-transferring element in thermal contact with the heat-transferring layer, the heat-transferring layer comprises an electrically insulating material, which at least partially overlaps at least one of the first and second surface; and
connection means configured to electrically connect the first pad and the second pad with a first terminal and a second terminal arranged on either the support substrate or the heat-transferring layer.

According to one embodiment, the heat-transferring layer is in contact with the first pad and the second pad.

According to one embodiment, the heat-transferring layer is made of a material, called a heat-transferring material, which has a thermal conductivity greater than or equal to 20 W/m/K, the heat-transferring layer advantageously comprising at least one of the materials chosen from: a polymeric material, AlN or silicon.

According to one embodiment, the waveguide is made of silicon, or of silicon nitride or of a hybrid form of silicon nitride and silicon.

According to one embodiment, the photonic device also comprises second means configured to dissipate heat capable of being emitted by the laser source to the support, the second means comprising second vias that extend, in the direction of the main face, and from the waveguide.

According to one embodiment, the second means also comprise a metal insert of generally planar shape and interposed between the second vias and the main face, the second means further comprising second terminal vias, which extend from the metal insert to the main face, and an additional insert is advantageously inserted between the main face and the second terminal vias.

According to one embodiment, the photonic device also comprises third means configured to dissipate heat capable of being emitted by the laser source, the third means comprising third vias that extend, in the direction of the main face, and from, respectively, the first pad and the second pad.

According to one embodiment, the third means also comprise two metal inserts called, respectively, the first insert and the second insert, of generally planar shape, the first insert being interposed between the main face and the third via, which extends from the first pad, the second insert being interposed between the main face and the third via, which extends from the second pad, the third means further comprising at least a third terminal via that extends from the first insert to the main face, and at least one other third terminal via that extends from the second insert to the main face.

According to one embodiment, the support face is assembled with a face of the support layer, referred to as the secondary face, opposite the main face of the support layer.

According to one embodiment, the overlapping by the heat-transferring layer of one of the first and the second surface is partial, and leaves free access to a first section and a second section, respectively, of the first surface and of the second surface, a first wire directly connects the first terminal and the first pad, while a second wire directly connects the second terminal and the second pad, the first terminal and the second terminal being arranged on the support substrate.

According to one embodiment, the heat-transferring layer comprises two secondary metal pads, called, respectively, the first secondary pad and the second secondary pad accessible by a contact face of the heat-transferring layer opposite the upper face, a first metal ball connecting the first secondary pad and the first pad, and a second metal ball connecting the second secondary pad and the second pad, the first terminal and the second terminal being arranged on the contact face, the first terminal and the first secondary pad being connected via a first redistribution line, while the second terminal and the second secondary pad are connected via a second redistribution line.

According to one embodiment, the support face is assembled to the photonic layer by the upper face by way of metal balls also ensuring the electrical connection of the first and second pads with, respectively, the first terminal and the second terminal, the support substrate comprising a through-opening passing through the support substrate of the support face toward a face of the support substrate opposite the support face, the through-opening being configured to allow the positioning of the first means.

According to one embodiment, the photonic device comprises coupling means configured to inject a laser radiation emitted by the laser source into an optical fiber or a network of optical fibers.

According to one embodiment, the coupling means are configured to allow coupling by an edge, called the coupling edge, of the device perpendicular to the main face, and, advantageously, the coupling means comprise a lens associated with the coupling edge.

According to one embodiment, the coupling means comprises a diffraction grating arranged in the photonic layer and configured to allow optical coupling by the upper face of the laser radiation emitted by the laser source and an optical fiber or a network of optical fibers.

### BRIEF DESCRIPTION OF THE DRAWINGS

Other features and advantages of the present disclosure will emerge from the following detailed description of example embodiments of the present disclosure with reference to the accompanying figures, in which:

FIG. 1 is a schematic representation of a photonic device provided with a source made of III-V semiconductor material known from the prior art;

FIG. 2A is a schematic representation of a photonic device according to a first embodiment of the present disclosure and for which only the first means are represented, and the photonic device is, in particular, represented along a cross-sectional plane perpendicular to the main face;

FIG. 2B is a schematic representation of a photonic device according to a first embodiment of the present disclosure and for which the first, second, and third means are represented, and the photonic device is, in particular, represented along a cross-sectional plane perpendicular to the main face;

FIG. 3 is a schematic representation of an example of a photonic device according to the embodiment shown in FIG. 1, FIG. 3 is, in particular, simplified for the sake of clarity, in particular, in this example, the photonic layer is formed by a stack of a first layer, a second layer and a third layer, the photonic device is, in particular, represented along a cross-sectional plane perpendicular to the main face;

FIG. 4 is a schematic representation of a photonic stack capable of being implemented in a photonic device according to the present disclosure, for the sake of clarity, the photonic stack is shown isolated from the photonic device and along a cross-sectional plane perpendicular to the main face;

FIG. 5 is a schematic representation of a waveguide capable of being implemented in a photonic device according to the present disclosure, for the sake of clarity, the waveguide is shown isolated from the photonic device and along a cross-sectional plane perpendicular to the main face;

FIG. 6 is a simplified representation of the device of FIG. 1 detailing the arrangement of the second means;

FIG. 7 is a simplified representation of the device of FIG. 1 detailing the arrangement of the third means;

FIG. 8 is a diagrammed, simplified representation of a photonic device provided with coupling means according to a second example, the photonic device being, in particular, represented along a cross-sectional plane perpendicular to the main face;

FIG. 9 is a diagrammed, simplified representation of a photonic device provided with coupling means according to a first example, the photonic device being, in particular, represented along a cross-sectional plane perpendicular to the main face;

FIG. 10 is a view of the front face of a photonic device provided with a plurality of laser sources and a first means common to all the laser sources;

FIG. 11 shows a photonic device according to the present disclosure and which comprises a control chip;

FIG. 12 is a schematic representation of a photonic device according to a second embodiment of the present disclosure, the photonic device being, in particular, represented along a cross-sectional plane perpendicular to the main face;

FIG. 13 is a schematic representation of a photonic device according to a third embodiment of the present disclosure, the photonic device being, in particular, represented along a cutting plane perpendicular to the main face.

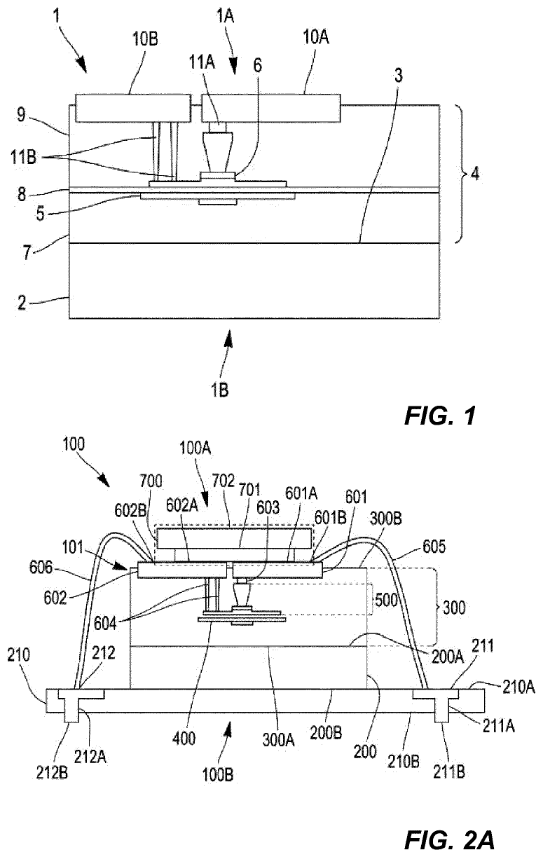

### DETAILED DESCRIPTION

The present disclosure relates to a photonic device and more particularly to a photonic device that comprises a photonic chip provided with a heterogeneous laser source and heat-dissipating means configured to dissipate the heat likely to be emitted by the laser source.

More particularly, the present disclosure relates to a photonic device that comprises a photonic chip and a support substrate, the photonic chip comprising a support layer, and a photonic layer. In particular, the photonic layer rests, by its lower face, on a main face of the support layer. Furthermore, the photonic layer, which comprises at least one dielectric material, encapsulates a laser source formed by a waveguide and a photonic stack optically coupled to one another.

The photonic chip also comprises a first pad and a second pad having, respectively, a first surface and a second surface, accessible by an upper face of the photonic layer opposite the lower layer. In this respect, the first pad and the second pad are electrically connected to the photonic stack by means of connection vias that extend in the photonic layer.

Furthermore, the heat-dissipating means comprise first means configured to dissipate heat that can be emitted by the laser source.

More particularly, the first means comprise a heat-transferring layer and a heat-transferring element exclusively in contact with the heat-transferring layer. The heat-transferring layer, in particular, comprises an electrically insulating material that partially overlaps at least one of the first and the second surface, leaving free access to a first section and a second section, respectively, of the first and second surfaces.

This particular arrangement of the heat-transferring layer thus makes it possible to electrically connect, with connection means, the first and the second section with the metal tracks of the support substrate at a support face of the substrate.

The heat-dissipating means may also comprise second and third means configured to dissipate heat that can be emitted by the laser source.

The second and the third means comprise, respectively, second and third vias that extend, in the direction of the main face, and from the waveguide, respectively, and from one and/or the other of the first pad and the second pad.

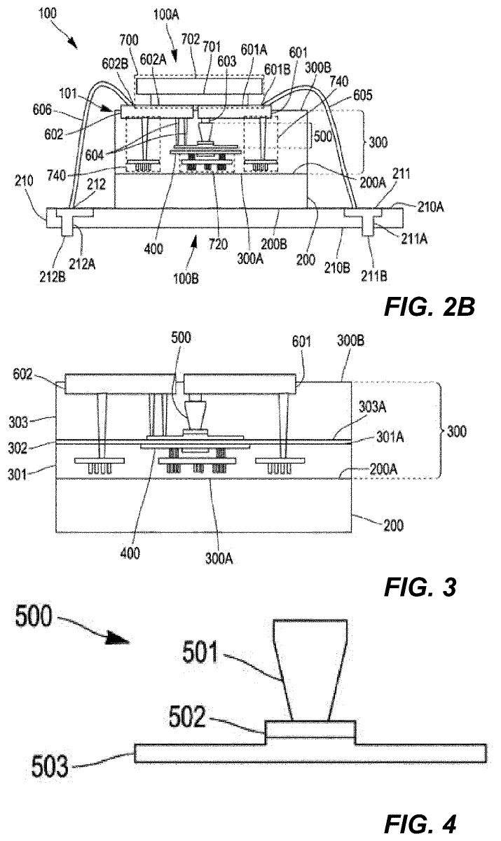

In FIG. 2A, a photonic device 100 according to one embodiment of the present disclosure can be seen. The photonic device 100 comprises a photonic chip 101, which comprises, from a rear face 100B toward a front face 100A, a support layer 200 and a photonic layer 300. The photonic device 100 also comprises a support substrate 210 provided with two parallel faces called, respectively, the support face 210A and the free face 210B. More particularly, the support substrate 210 comprises, on its support face 210A, a first terminal 211 and a second terminal 212. More particularly, the first terminal 211 and the second terminal 212 are configured to allow the control and/or the interfacing of the photonic device 100 with control means. In this respect, the first terminal 211 and the second terminal 212, accessible by the support face, extend depending on the thickness of the support substrate 210 by way, respectively, of a first via 211A and a second via 212A. The first via 211A and the second via 212A being arranged to allow an electrical connection via the free face 210B. For example, a first pad 211B and a second pad 212B can be arranged on the free face 210B, in the extension, respectively, of the first via 211A and of the second via 212A.

The support layer 200 comprises two faces, parallel to each other, respectively, main face 200A and secondary face 200B, while the photonic layer 300 also comprises two faces parallel with the main face 200A and called, respectively, the lower face 300A and the upper face 300B. In this respect, and as shown in FIG. 2A, the photonic layer 300 rests on the main face 200A by its lower face 300A, while the support layer rests on the support face 210A by its secondary face 200B.

The support layer 200 may comprise a semiconductor material and more particularly a monocrystalline semiconductor material. In this respect, the support layer 200 may advantageously comprise monocrystalline silicon. This material is known to be compatible with the manufacturing lines of microelectronic and/or photonic components and has a high heat dissipation coefficient, the advantage of which will be mentioned below.

The photonic layer 300 comprises at least one layer of dielectric material, wherein a waveguide 400 and a photonic stack 500 are encapsulated. More particularly, the photonic stack 500 comprises a plurality of layers of III-V semiconductor materials, and is optically coupled with the waveguide 400 so as to form therewith a heterogeneous laser source. More particularly, the photonic stack 500 may comprise a plurality of layers of III-V semiconductor materials structured in a second waveguide that is optically coupled to the waveguide 400.

In other words, a laser radiation capable of being emitted by the photonic stack 500 will be coupled to and guided by the waveguide 400.

Thus, and as an example and as shown in FIG. 4 (FIG. 4 representing the photonic stack isolated from the rest of the photonic device), the photonic stack 500 may comprise, from the front face 100A to the rear face 100B, an upper layer 501, one or more quantum well layers 502, and a lower layer 503. In particular, the upper layer 501 may comprise a P-doped III-V semiconductor material, while the lower layer 503 may comprise an N-doped III-V semiconductor material. More particularly, the upper layer 501 and the lower layer 503 may comprise, respectively, P- and N-doped InP. The quantum well layer(s) 502 may comprise one or more III-V semiconductor materials, for example, InP-based materials.

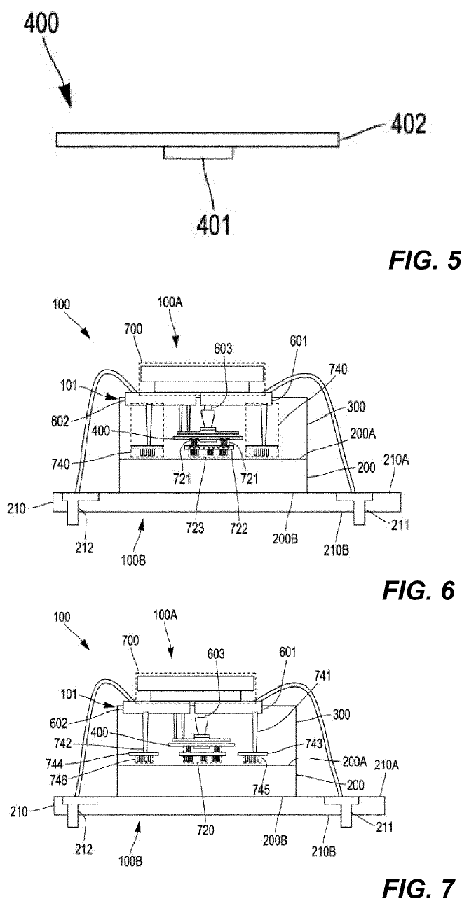

Furthermore, the photonic stack 500 is advantageously arranged in line with the waveguide 400. As for the waveguide 400, as shown in FIG. 5 (FIG. 5 representing the waveguide isolated from the rest of the photonic device), it may comprise a central rib 401 and a base 402 resting on the central rib 401 so as to have a T-shaped profile along a cross-sectional plane perpendicular to the first face. The purpose of this T-shaped profile aspect is not to limit the scope of the present disclosure to this geometry alone, and a person of ordinary skill in the art will be able to design a waveguide with a different profile. For example, a guide with a square or even rectangular cross-section could be considered.

It is also understood that the material forming the waveguide 400 has a refractive index greater than that of the dielectric material forming the photonic layer 300.

The photonic chip 101 also comprises two contact pads, called the first pad 601 and the second pad 602. More particularly, the first pad 601 and the second pad 602 have, respectively, a first surface 601A and a second surface 602A, accessible by the upper face 300B of the photonic layer 300. In particular, the first pad 601 and the second pad 602 are electrically connected to the photonic stack 500 by way of connection vias 603, 604, which extend in the photonic layer 300.

As an example, the contact pads may comprise aluminum and have a thickness on the order of 3 μm.

The term “accessible by the upper face” is understood to mean a contact pad that has a surface (the first surface and the second surface) flush or in projection with respect to the upper face. It is also understood, without it being necessary to specify it, that the first surface and the second surface are parallel, or at least substantially parallel, to the main face 200A. As a result, the first surface and the second surface are parallel to one another.

The first pad 601 can be connected to the upper layer 501 of the photonic stack 500 by way of a connection via called the first via 603, while the second pad 602 can be connected to the lower layer 503 of the photonic stack 500 by way of another connection via called the second contact via 604.

It is understood that the contact pads 601, 602 and the connection vias 603, 604 comprise an electrically conductive material, more particularly a metal, for example, aluminum and/or copper.

The contact pads 601, 602 and the connection vias 603, 604, as previously described, make it possible to impose the circulation of a current within the photonic stack 500, and consequently, the emission of laser radiation by the latter. The emitted laser radiation is then coupled and subsequently guided by the waveguide 400.

It is known that the laser source formed by the waveguide 400 and the photonic stack 500 is likely to heat up when it is in operation. This heating may alter the operation of the laser source and ultimately degrade performance.

Thus, the present disclosure also implements first heat-dissipating means 700 configured to dissipate heat that can be emitted by the laser source (FIG. 2A).

Advantageously, the present disclosure can also implement second means 720 and third means 740 configured to dissipate heat that can be emitted by the laser source (FIG. 2B).

In this respect, the first heat-dissipating means 700 comprise a heat-transferring layer 701 and a heat-transferring element 702.

According to this first embodiment, the heat-transferring layer 701 comprises an electrically insulating material, which is partially overlapping at least one of the first surface 601A and the second surface 602A, leaving free access to a first section 601B and a second section 602B, respectively, from the first surface 601A and the second surface 602A.

It is therefore understood that when the heat-transferring layer 701 is in contact with a contact pad, it overlaps the first and/or the second surface of the pad under consideration, and this covering is only partial so as to allow contact to be taken up at the first section 601B and the second section 602B, for example, by way of a welded wire.

In particular, the photonic device 100 also comprises connection wires, respectively, the first wire 605 and the second wire 606. More particularly, the first wire 605 directly connects the first section 601B with the first terminal 211, while the second wire 606 directly connects the second section 602B with the second terminal 212.

Advantageously, the heat-transferring layer is made of a material, called heat-transferring material, which has a thermal conductivity greater than or equal to 20 W/m/K, for example, a heat-transferring layer having a thickness of 150 μm and composed of a material having a thermal conductivity equal to 130 W/m/K may be considered.

In particular, the heat-transferring material may comprise a dielectric material sold by the company T-global™ sold under the product name Thermal Tape.

The choice of the heat-transferring material is accessible to a person of ordinary skill in the art.

The heat-transferring material also has an electrical resistivity greater than 10¹² Ohm·cm.

As an example, the thickness of the heat-transferring layer may be 0.15 μm. However, a person skilled in the art will be able to adjust the thickness of the heat-transferring layer as a function of the resistivity of the material under consideration.

The heat-transferring element 702 is advantageously exclusively in contact with the heat-transferring layer 701. In other words, the heat-transferring element 702 is electrically isolated from both the first pad 601 and the second pad 602.

The heat-transferring element may comprise at least one of the elements chosen from: a metal plate, a thermoelectric cooling plate, an air-cooled radiator, a plate provided with cooling ducts (for example, ducts allowing circulation of a fluid, in particular, water).

However, the present disclosure is not limited to these only elements, and a person skilled in the art may implement any other type of cooling element that may be suitable.

Advantageously, the heat-transferring element 702 can be configured to be thermalizable.

The term “thermalizable” is understood to mean a heat-transferring element capable of imposing a given temperature.

According to one example shown in FIG. 3, the photonic layer 300 comprises, from the main face 200A, a first layer 301, a second layer 302 and a third layer 303. More particularly, and still according to this example, the waveguide 400 is arranged in the first layer and is flush with the interface, called the first interface 301A, formed between the first layer 301 and the second layer 302, while the photonic stack 500 is arranged in the third layer 303 and is flush with the interface, called the second interface 303A, formed between the second layer 302 and the third layer 303.

It is also notable that the second layer 302 is optional.

Thus, as soon as the laser source is in operation, the heat that the laser emits is drained through the connection vias 603, 604 and the contact pads to the first heat-dissipating means 700 and, in particular, to the heat-transferring element 702. The consideration of a heat-transferring layer made of an electrically insulating material makes it possible to consider heat dissipation by cooperation with both the first pad and the second pad.

Thus, the first means, as considered in the present disclosure, make it possible to limit the heating up of the laser source while it is operating. More particularly, during the implementation of the first means alone, a temperature difference between the laser source and the heat dissipation plate less than 10° C. was observed, whereas without implementing the first means, a temperature difference between the support layer 200 and the laser source between 20° C. and 30° C. would be observed. The limitation and/or the control of the heating of the laser source according to the principles of the present disclosure makes it possible to improve the stability of the laser source.

As shown in FIG. 2B, the photonic device 100 may also comprise second means 720 configured to dissipate heat capable of being emitted by the laser source to the support layer 200.

The second means 720 comprise second vias 721, which extend from the waveguide 400 to the main face 200A. More particularly, the second vias 721 extend in the first layer 301 if it is considered (FIG. 6).

In a complementary manner, the second means 720 may also comprise a metal insert 722 of generally planar shape and interposed between the second vias 721 and the main face 200A. The second means 720 may also comprise second terminal vias 723, which extend from the metal insert 722 toward the main face 200A.

It is understood that all of the elements forming the second heat-dissipating means may comprise an electrically conductive material, and, in particular, a metal, for example, copper. The second via, the metal insert and the second terminal vias are connected together.

Thus, when heat is emitted by the laser source, that heat is dissipated by way of the first heat-dissipating means 700 and the second means 720. In this respect, the second means 720 make it possible to dissipate the heat in the support layer 200. The implementation of the first means and second means makes it possible to observe a temperature difference between the laser source and the heat dissipation plate less than 8° C. Implementing only the second means would make it possible to observe a temperature difference between the support layer 200 and the laser source of 13° C. to 17° C.

As shown in FIG. 2B, the photonic device 100 also comprises third means 740 configured to dissipate heat capable of being emitted by the laser source to the support layer 200. The third means 740 comprising third vias 741, 742, which extend from, respectively, the first pad 601 and the second pad 602 toward the main face 200A (FIG. 7).

The third means 740 also comprise two metal inserts called, respectively, the first insert 743 and the second insert 744, of generally planar shape. The first insert 743 is in contact with the third via 741, which extends from the first pad 601, and is interposed between the main face 200A and the third via 741. The second insert 744 is in contact with the third via 742, which extends from the second pad 602 and is interposed between the main face 200A and the third via 742.

Advantageously, the metal insert 722, the first insert 743, and second insert 744 are formed from a single metal level. In other words, the distance separating an insert from the main face is the same for each of the inserts.

The third means 740 may further comprise one or more third terminal vias 745, which extend from the first insert 743 to the main face 200A, and one or more other terminal vias 746, which extend from the second insert 744 toward the main face 200A.

It is understood that all of the elements forming the third means 740 may comprise an electrically conductive material, and, in particular, a metal, for example, copper.

These third means 740 taken in combination with the first means and the second means make it possible to observe a temperature difference between the laser source and the heat dissipation plate less than 7° C.

The photonic device 100 may also comprise coupling means configured to inject laser radiation emitted by the laser source into an optical fiber or an array of optical fibers.

According to a first example, the coupling means are configured to allow coupling by an edge, called the coupling edge face 200C, of the device perpendicular to the main face 200A. This aspect is shown in FIG. 8. Advantageously, the coupling means comprise a waveguide 804, and a lens 800 associated with the coupling edge face 200C. These coupling means thus make it possible to couple the light radiation emitted by the laser source to an external device, for example, to an optical fiber 801.

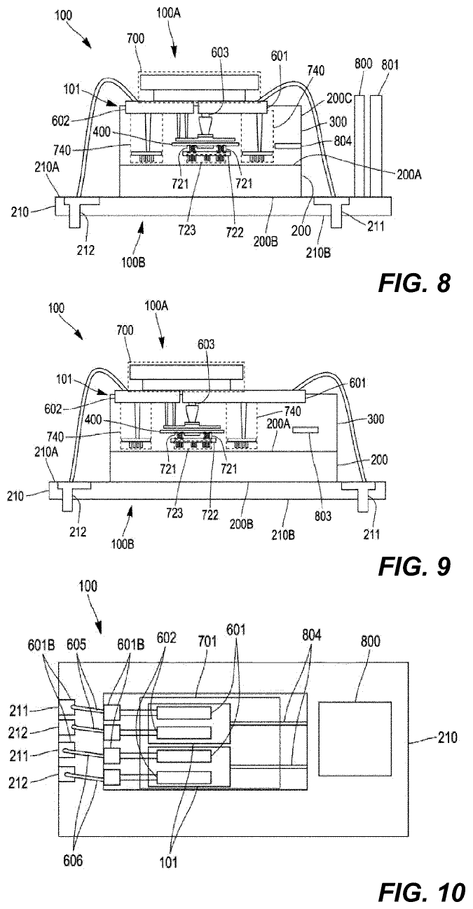

According to a second example, the coupling means comprise a diffraction grating 803 arranged in the photonic layer and configured to allow optical coupling, by the front face, of the laser radiation emitted by the laser source and an optical fiber or a network of optical fibers. This aspect is shown in FIG. 9.

Of course, the present disclosure is not limited to a single laser source. In this respect, a person skilled in the art, as shown in FIG. 10, may consider a photonic device 100 provided with a plurality of photonic chips 101, and a heat-transferring layer in contact with the first and second pad 601 and 602. According to this configuration, the coupling wafers of each of the photonic chips 101 can be coplanar. Furthermore, the first terminals 211 and the second terminals 212, arranged on the support face 210A, are opposite a face of the photonic chips opposite the coupling edge face 200C.

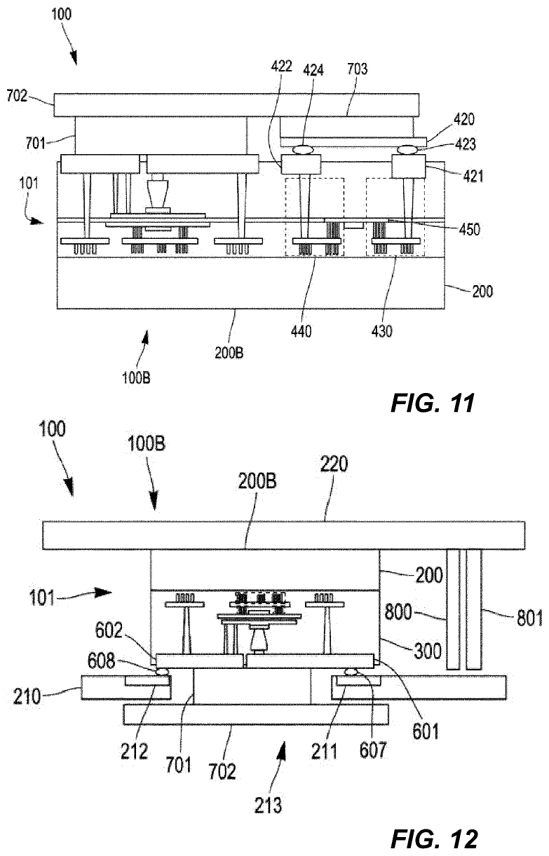

As shown in FIG. 11, the photonic device 100 may also comprise a control chip 420 and a modulator 450 (the modulator 450, in particular, comprises a waveguide encapsulated in the photonic layer). The control chip 420 rests, in particular, on two connector pads 421 and 422 accessible by the front face 100A. Metal balls 423, 424 can be interposed between the connector pads and the front face. The photonic device 100 may comprise an auxiliary heat-dissipating layer 703 thermally coupling the driving chip with the heat-transferring element 702. The auxiliary heat-dissipating layer 703 is made of the same material as the heat-transferring layer 701.

The photonic device 100 also comprises other heat-dissipating means 430 and 440, which essentially have the same features as the second and third dissipation means in order to dissipate the heat likely to be generated at the control chip 420 and the modulator 450.

In FIG. 12, the photonic device 100 can be seen according to a second embodiment of the present disclosure, which essentially takes up the elements relating to the first embodiment.

According to this second embodiment, the support face is assembled to the photonic layer by the upper face by means of metal balls 607, 608 also ensuring the electrical connection of the first and second pads 601 and 602 with the first terminal 211 and the second terminal 212. According to this second embodiment, the support substrate 210 comprises a through-opening 213 passing through the support substrate from the support face to the free face, the through-opening being configured to allow the positioning of the first heat-dissipating means 700.

The photonic device 100 according to this second embodiment may also comprise an additional substrate 220 on a face of which the secondary face 200B of the support layer 200 is assembled and the lens 800 and the network of optical fibers 801.

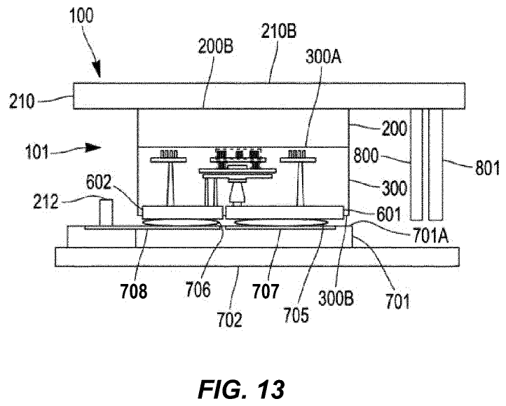

In FIG. 13, the photonic device 100 can be seen according to a third embodiment of the present disclosure, which essentially takes up the elements relating to the first embodiment.

According to this third embodiment, the heat-transferring layer 701 comprises two secondary metal pads, called, respectively, first secondary pad 707 and second secondary pad 708 accessible by a contact face 701A of the heat-transferring layer 701 opposite the upper face 300B.

A first metal ball 705, for example, made of AuSn, connects the first secondary pad 707 and the first pad 601, and a second metal ball 706 connects the second secondary pad 708 and the second pad 602.

The first terminal 211 and the second terminal 212 (not shown in FIG. 13 for the sake of clarity) are electrically linked, respectively, to the first secondary pad 707 and to the second secondary pad 708 via redistribution lines.

According to this third embodiment, the heat-transferring layer 701 advantageously comprises silicon or AlN. These two materials are particularly suitable for the formation of connection means, such as redistribution lines.

The present disclosure therefore proposes an effective solution for dissipating the heat that can be emitted by a laser in operation and thus ensures stability. In particular, the present disclosure proposes to implement first means making it possible to dissipate the heat likely to be produced by the laser source, which cooperate with means for connecting the laser source.

A method for manufacturing the photonic device may involve manufacturing steps well known in the field of microelectronics.

Of course, the present disclosure is not limited to the described embodiments and variant embodiments may be envisaged without departing from the scope of the invention as defined by the claims.

### REFERENCES

[1] S. Menezo et al., “Back-Side-On-BOX heterogeneous laser intégration for fully integrated photonic circuits on Silicon” 45th European Conférence on Optical Communication (ECOC 2019), 2019, pp. 1-3;
[2] M. N. Sysak et al., “Hybrid Silicon Laser Technology: A Thermal Perspective” in IEEE Journal of Selected Topics in Quantum Electronics, vol. 17, no. 6, pp. 1490-1498 November-December 2011;
[3] C. Zhang et al., “Thermal Management of Hybrid Silicon Ring Lasers for High Temperature Operation” in IEEE Journal of Selected Topics in Quantum Electronics, vol. 21, no. 6, pp. 385-391, November-December 2015;
[4] US 2014/0376857 A1.

1. A photonic device comprising a photonic chip and a support substrate, the support substrate having a support face, the photonic chip comprising a support layer and a photonic layer resting by a lower face thereof on a main face of the support layer, the photonic layer comprising at least one dielectric material and encapsulating at least one laser source formed by a waveguide and a photonic stack optically coupled together, the photonic stack being comprising III-V semi-conductor materials, the photonic chip also comprising a first metal pad and a second metal pad having, respectively, a first surface and a second surface, surface accessible by an upper face of the photonic layer opposite the lower face, and electrically connected to the photonic stack by way of connection vias, the connection vias extending in the photonic layer, the first metal pad and the second metal pad being configured to allow circulation of an electric current in the photonic stack to control an emission of a laser radiation by the laser source, the photonic device further comprising:
first heat-dissipating means configured to dissipate heat capable of being emitted by the laser source, the first heat-dissipating means comprising a heat-transferring layer and a heat-transferring element in thermal contact with the heat-transferring layer, the heat-transferring layer comprising an electrically insulating material at least partially overlapping at least one of the first surface of the first metal pad and the second surface of the second metal pad; and
connection means configured to electrically connect the first metal pad and the second metal pad with a first terminal and a second terminal arranged on either the support substrate or the heat-transferring layer.

2. The photonic device of claim 1, wherein the heat-transferring layer is in contact with the first metal pad and the second metal pad.

3. The photonic device of claim 1, wherein the heat-transferring layer a heattransferring material, having a thermal conductivity greater than or equal to 20 W/m/K.

4. The photonic device of claim 1, wherein the waveguide comprises silicon, silicon nitride, or a hybrid form of silicon nitride and silicon.

5. The photonic device of claim 1, further comprising second means configured to dissipate the heat capable of being emitted by the laser source to the support layer, the second means comprising second vias extending in a direction of the main face, and from the waveguide.

6. The photonic device of claim 5, wherein the second means further comprise a metal insert of generally planar shape and interposed between the second vias and the main face, the second means further comprising second terminal vias, extending from the metal insert toward the main face.

7. The photonic device of claim 1, further comprising third means configured to dissipate the heat likely to be emitted by the laser source, the third means comprising third vias extending in the direction of the main face, and from, respectively, the first pad and the second pad.

8. The photonic device of claim 7, wherein the third means further comprise two metal inserts, respectively, a first insert and a second insert, the first insert and the second insert being generally planar in shape, the first insert being interposed between the main face and the third via extending from the first pad, the second insert interposing between the main face and the third via extending from the second pad, the third means further comprising at least a third terminal via extending from the first insert to the main face, and at least another third terminal via extending from the second insert to the main face.

9. The photonic device of claim 1, wherein the support face is assembled with a secondary face of the support layer opposite the main face of the support layer.

10. The photonic device of claim 9, wherein the heat-transferring layer covers only a portion of each of the first surface and the second surface and leaves access to a first section of the first surface and a second section of the second surface, a first wire directly connecting the first terminal and the first metal pad, and a second wire directly connecting the second terminal and the second metal pad, the first terminal and the second terminal being disposed on the support substrate.

11. The photonic device of claim 9, wherein the heat-transferring layer comprises a first secondary metal pad and a second secondary metal pad accessible by a contact face of the heat-transferring layer opposite the upper face of the photonic laver, a first metal ball connecting the first secondary metal pad and the first metal pad, and a second metal ball connecting the second secondary metal pad and the second metal pad, the first terminal and the second terminal disposed on the contact face, the first terminal and the first secondary metal pad being connected via a first redistribution line, and the second terminal and the second secondary metal pad being connected via a second redistribution line.

12. The photonic device of claim 1, wherein the support face is assembled to the upper face of the photonic layer by way of metal balls that also ensure electrical connection of the first metal pad and the second metal pad with, respectively, the first terminal and the second terminal, the support substrate comprising a through-opening passing through the support substrate, the through-opening configured to allow positioning of the first heat-dissipating means.

13. The photonic device of claim 1, further comprising coupling means configured to inject laser radiation emitted by the laser source into an optical fiber or a network of optical fibers.

14. The photonic device of claim 13, wherein the coupling means are configured to allow coupling, by a coupling edge of the photonic device perpendicular to the main face, of the laser radiation emitted by the laser source and an optical fiber or a network of optical fibers.

15. The photonic device of claim 13, wherein the coupling means comprise a diffraction grating disposed in the photonic layer and configured to allow optical coupling, by the upper face, of the laser radiation emitted by the laser source and an optical fiber or a network of optical fibers.

16. The photonic device of claim 3, wherein the heat-material comprises at least one material selected from among: a polymer material, AlN, or silicon.

17. The photonic device of claim 6, further comprising an additional insert between the main face and the second terminal vias.

18. The photonic device of claim 14, wherein the coupling means further comprises a lens associated with the coupling edge.

19. The photonic device of claim 6, further comprising third means configured to dissipate the heat likely to be emitted by the laser source, the third means comprising third vias extending in the direction of the main face, and from, respectively, the first pad and the second pad.

20. The photonic device of claim 7, wherein the third means further comprise two metal inserts, respectively, a first insert and a second insert, the first insert and the second insert being generally planar in shape, the first insert being interposed between the main face and the third via extending from the first pad, the second insert interposing between the main face and the third via extending from the second pad, the third means further comprising at least a third terminal via extending from the first insert to the main face, and at least another third terminal via extending from the second insert to the main face.
